(19) United States
(12) Patent Application Publication
(10) Pub. No.: US 2012/0012930 A1
(43) Pub. Date: Jan. 19, 2012

(54) SEMICONDUCTOR DEVICE AND METHOD FOR MANUFACTURING THE SAME

(75) Inventors: Kumiko Sato, Hyogo-ken (JP); Hirofumi Hirasozu, Kanagawa-ken (JP); Tomoko Matsudai, Tokyo (JP)

(73) Assignee: KABUSHIKI KAISHA TOSHIBA, Tokyo (JP)

(21) Appl. No.: 13/109,233

(22) Filed: May 17, 2011

(30) Foreign Application Priority Data
Jul. 14, 2010 (JP) 2010-159641

(51) Int. Cl. H01L 29/78; H01L 21/336

(52) U.S. Cl. 257/336; 438/268; 257/E29.262; 257/E21.41

(57) ABSTRACT

According to one embodiment, a semiconductor device includes a semiconductor substrate, and first and second transistors. The substrate has a first conductivity type. The first and second transistors are provided on the substrate. The first and second transistors each include a gate electrode provided on the substrate, a gate insulating film provided between the substrate and the gate electrode, a source and a drain region of a second conductivity type, and a high-concentration channel region of the first conductivity type. The source and drain regions are provided in regions of an upper portion of the substrate. A region directly under the gate electrode is interposed between the regions. The high-concentration channel region is formed on a side of the source region of the region of the upper portion directly under the gate electrode. The high-concentration channel region has an effective impurity concentration higher than that of the upper portion.

### CROSS-REFERENCE TO RELATED APPLICATIONS

This application is based upon and claims the benefit of priority from the prior Japanese Patent Application No. 2010-159641, filed on Jul. 14, 2010; the entire contents of which are incorporated herein by reference.

### FIELD

Embodiments described herein relate generally to a semiconductor device and a method for manufacturing the same.

### BACKGROUND

In a normal MOSFET (Metal-Oxide-Semiconductor Field-Effect Transistor), for example, a p-type channel region is formed between an n-type source region and an n-type drain region. Such a structure unfortunately has poor hot carrier resistance because the p-type channel region, which has a high impurity concentration, contacts the n-type drain region, which has a high impurity concentration. In the case where the gate length is increased to improve the hot carrier resistance, the gate capacitance undesirably increases; it is difficult to increase the switching speed; and the dedicated surface area of the MOSFET undesirably increases.

To solve such problems, a GCMOS (Graded Channel MOS) transistor has been proposed in which the impurity concentration of the portion of the channel region on the drain side is lower than the impurity concentration of the portion on the source side. Because the high impurity concentration region of the channel region is distal to the drain region in the GCMOS transistor, the electric field between the channel region and the drain region is relaxed when a voltage is applied between the source/drain; and the hot carrier resistance improves. Therefore, the GCMOS transistor has higher reliability than the normal MOSFET.

However, because the high impurity concentration region of the channel region is distal to the drain region in the GCMOS transistor, it is necessary to partially form the high impurity concentration region of the channel region only in a portion of the region directly under the gate electrode. Therefore, positional alignment is necessary between the implantation process used to form the channel region and the formation process of the gate electrode. Such positional alignment is unnecessary in a normal MOSFET. That is, the need for this positional alignment in the GCMOS undesirably causes fluctuation of the electrical characteristics caused by the process fluctuation to occur easily as the element is downsized and particularly as the gate length is reduced. Further, in the case where two GCMOS transistors are used as a pair, the difference of the electrical characteristics between the two GCMOS transistors undesirably increases as the effects of the process fluctuation increase.

### BRIEF DESCRIPTION OF THE DRAWINGS

FIG. 1 is a plan view illustrating a semiconductor device according to a first embodiment;

FIG. 2 is a cross-sectional view of main components along line A-A′ illustrated in FIG. 1;

FIGS. 3A to 3C, FIGS. 4A to 4C, and FIG. 5 are cross-sectional views of processes, illustrating a method for manufacturing the semiconductor device according to the first embodiment;

FIG. 6 is a graph illustrating the relationship between the element size and the pairability;

FIG. 7 is a plan view illustrating a semiconductor device according to a second embodiment; and

FIG. 8A is a cross-sectional view illustrating a semiconductor device according to a third embodiment and FIGS. 8B and 8C are cross-sectional views of processes, illustrating a method for manufacturing the semiconductor device according to the third embodiment.

### DETAILED DESCRIPTION

In general, according to one embodiment, a semiconductor device includes a semiconductor substrate, and first and second transistors. The semiconductor substrate has a first conductivity type. The first and second transistors are provided on the semiconductor substrate. The first and second transistors each include a gate electrode provided on the semiconductor substrate, a gate insulating film provided between the semiconductor substrate and the gate electrode, a source region and a drain region of a second conductivity type, and a high-concentration channel region of the first conductivity type. The source region and the drain region are provided in regions of an upper portion of the semiconductor substrate. A region directly under the gate electrode is interposed between the source region and the drain region. The high-concentration channel region is formed on a side of the source region of the region of the upper portion directly under the gate electrode. The high-concentration channel region has an effective impurity concentration higher than an effective impurity concentration of the upper portion. The direction from the source region of the first transistor toward the drain region of the first transistor has an orientation being substantially same as a direction from the source region of the second transistor toward the drain region of the second transistor.

In general, according to one embodiment, a method is disclosed for manufacturing a semiconductor device. The method can include partitioning a first region and a second region by selectively forming an element isolation insulating film in an upper portion of a semiconductor substrate. The upper portion has a first conductivity type. The method can include forming a gate insulating film in an upper face of the semiconductor substrate. The method can include selectively forming a first mask material on the gate insulating film on a side of one-direction of a region directly above the first region and on the gate insulating film on a side of the one-direction of a region directly above the second region. The method can include forming a high-concentration channel region in a portion of the upper portion of the semiconductor substrate by implanting a first conductivity-type impurity using the first mask material as a mask. The method can include removing the first mask material. The method can include forming a conductive film on the gate insulating film. The method can include selectively forming a second mask material on the conductive film. The method can include forming a gate electrode by selectively removing the conductive film by performing etching using the second mask material as a mask. The method can include forming an LDD region by implanting a second conductivity-type impurity using the gate electrode as a mask. The method can include forming a sidewall on a side face of the gate electrode. In addition, the method can include forming a source region and a drain region in the upper portion of the semiconductor substrate by implanting the second conductivity-type impurity using the gate electrode and the sidewall as a mask.

Various embodiments will now be described hereinafter with reference to the accompanying drawings.

First, a first embodiment will be described.

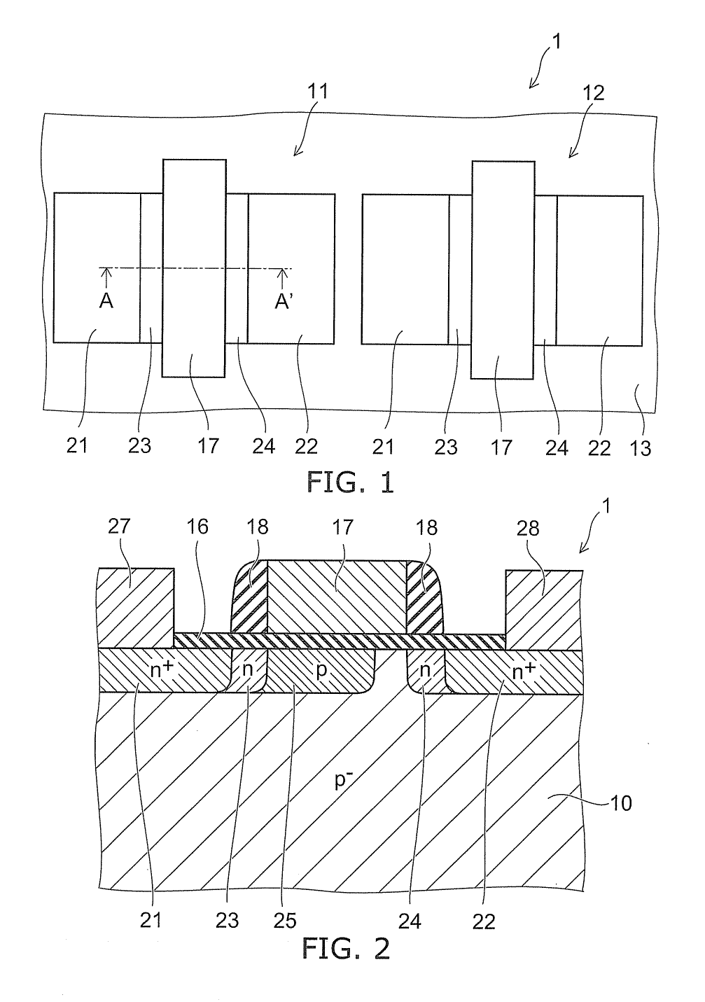

FIG. 1 is a plan view illustrating the semiconductor device according to the embodiment.

FIG. 2 is a cross-sectional view of main components along line A-A′ illustrated in FIG. 1.

For convenience of illustration in FIG. 1, a gate insulating film 16, a sidewall 18, a source electrode 27, and a drain electrode 28, which are described below, are not illustrated.

A semiconductor substrate 10 is provided in the semiconductor device 1 according to the embodiment as illustrated in FIG. 1 and FIG. 2. At least an upper portion of the semiconductor substrate 10 is, for example, a p⁻-type high-resistance semiconductor layer. The entire semiconductor substrate 10 may be a p⁻-type substrate of the p⁻-type; the semiconductor substrate 10 may be a substrate in which a p⁻-type well is formed in the upper portion of an n⁻-type substrate; and an n⁻-type epitaxial layer may be formed on a substrate and a p⁻-type well may be formed in the upper portion thereof.

Two transistors 11 and 12 are formed in the upper face of the semiconductor substrate 10. As described below, the transistors 11 and 12 are n-channel GCMOS transistors having the same design. The transistors 11 and 12 are formed in mutually adjacent regions of the upper face of the semiconductor substrate 10 and are electrically isolated by an element isolation insulating film 13. The transistors 11 and 12 are included in the same circuit and are used as a pair.

The configuration of the transistors 11 and 12 will now be described. Although the transistor 11 is described as an example in the description recited below, the configuration of the transistor 12 also is similar.

In the transistor 11, the gate insulating film 16 is provided on the semiconductor substrate 10; and a gate electrode 17 is provided on the gate insulating film 16. The gate electrode 17 has a line configuration extending in one direction as viewed from above. The sidewall 18 is provided on two side faces of the gate electrode 17. In one example, the semiconductor substrate 10 is made of monocrystalline silicon; the gate insulating film 16 is made of silicon oxide; the gate electrode 17 is made of polycrystalline silicon; and the sidewall 18 is made of silicon nitride, a silicon oxide film, or both. The width of the gate electrode 17, i.e., the gate length, is not more than, for example, 2.0 μm and is, for example, less than 0.8 μm.

A source region 21 and a drain region 22 of the n⁺ conductivity type are formed separated from each other in the upper portion of the semiconductor substrate 10 such that the region directly under the gate electrode 17 and directly under the sidewalls 18 is interposed between the source region 21 and the drain region 22. In the regions of the upper portion of the semiconductor substrate 10 directly under the sidewalls 18, n-type LDD (Lightly Doped Drain) regions 23 and 24 are formed. The LDD region 23 contacts the source region 21; and the LDD region 24 contacts the drain region 22. The effective impurity concentrations of the LDD regions 23 and 24 are lower than the effective impurity concentrations of the source region 21 and the drain region 22. In the specification, the concentration of the impurities contributing to the conduction of the semiconductor material is referred to as the effective impurity concentration. For example, in the case where the semiconductor material contains both an impurity that forms donors (hereinbelow referred to as an n-type impurity) and an impurity that forms acceptors (hereinbelow referred to as a p-type impurity), the concentration of the activated impurities excluding the cancelled portion of the donors and the acceptors is referred to as the effective impurity concentration.

The region of the upper portion of the semiconductor substrate 10 directly under the gate electrode 17, i.e., the region between the LDD region 23 and the LDD region 24, is used to form the channel region of the transistor 11. When a drive voltage of the threshold voltage or higher is applied to the gate electrode 17, an inversion layer is formed in the channel region. A high-concentration channel region 25 is formed in a region of the channel region on the source region 21 side. The conductivity type of the high-concentration channel region 25 is the p-type; and the effective impurity concentration thereof is higher than the effective impurity concentration of the upper portion of the semiconductor substrate 10. Although the high-concentration channel region 25 contacts the LDD region 23, the high-concentration channel region 25 does not contact the LDD region 24. Therefore, the effective impurity concentration of the channel region is relatively high at the portion on the source region 21 side and relatively low at the portion on the drain region 22 side. Although the lower faces of the source region 21, the drain region 22, the LDD regions 23 and 24, and the high-concentration channel region 25 are illustrated as being in the same plane in FIG. 2, this is not always limited thereto. The position of the lower face of each of the regions is determined by the concentration of the impurity, the acceleration voltage when implanting the impurity, the thermal history after the implantation, etc.

The source electrode 27 and the drain electrode 28 are provided on the semiconductor substrate 10. The source electrode 27 is disposed in the region directly above the source region 21 to contact the source region 21 with an ohmic connection. The drain electrode 28 is disposed in the region directly above the drain region 22 to contact the drain region 22 with an ohmic connection. A p⁺-type contact region (not illustrated) is formed in the upper portion of the semiconductor substrate 10 and is connected to, for example, the source electrode 27.

In the semiconductor device 1, the longitudinal direction of the gate electrode 17 of the transistor 11 is the same as the longitudinal direction of the gate electrode 17 of the transistor 12. In other words, the gate electrodes 17 of the transistors 11 and 12 are arranged with line configurations parallel to each other. The source region 21 and the drain region 22 are disposed on the same sides, respectively. In other words, the side of the transistor 11 on which the source region 21 is disposed as viewed from the gate electrode 17 is the same as the side of the transistor 12 on which the source region 21 is disposed as viewed from the gate electrode 17. Restated, the direction from the source region 21 of the transistor 11 toward the drain region 22 of the transistor 11 has the same orientation as the direction from the source region 21 of the transistor 12 toward the drain region 22 of the transistor 12. Having the same orientation is not limited to the case where two directions match perfectly; and it is sufficient for the angle between the two directions to be less than 90°. In the example illustrated in FIG. 1, for example, the direction from the source region 21 of the transistor 11 toward the drain region 22 of the transistor 11 matches the direction from the source region 21 of the transistor 12 toward the drain region 22 of the transistor 12.

The direction from the source region 21 of the transistor 11 toward the source region 21 of the transistor 12 matches the direction from the source region 21 of the transistor 11 toward the drain region 22 of the transistor 11. In other words, the source region 21 and the drain region 22 of the transistor 11 and the source region 21 and the drain region 22 of the transistor 12 are arranged in one column in this order. A method for manufacturing the semiconductor device according to the embodiment will now be described.

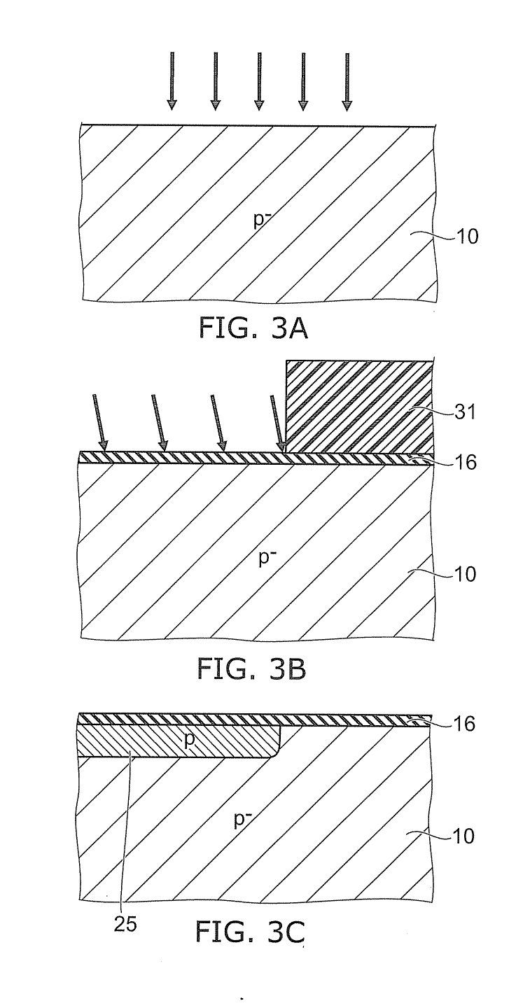

FIGS. 3A to 3C, FIGS. 4A to 4C, and FIG. 5 are cross-sectional views of processes, illustrating the method for manufacturing the semiconductor device according to the embodiment.

First, as illustrated in FIG. 3A, for example, a p⁻-type well is formed by ion implantation of the p-type impurity into the upper portion of an n⁻-type semiconductor substrate. Thereby, the semiconductor substrate 10 is constructed with a p⁻-type upper portion. Then, the regions where the transistors 11 and 12 are to be formed are partitioned by selectively forming the element isolation insulating film 13 (referring to FIG. 1) in the upper portion of the semiconductor substrate 10.

Then, as illustrated in FIG. 3B, the gate insulating film 16 is formed in the upper face of the semiconductor substrate 10. Then, a resist mask 31 is formed by forming a resist film on the gate insulating film 16 and performing patterning using photolithography. The resist mask 31 is formed to expose the region where the high-concentration channel region 25 is to be formed and to cover the other regions. In other words, the resist mask 31 is selectively formed on a one-direction side of the region directly above the region where the transistor 11 is to be formed and on the one-direction side of the region directly above the region where the transistor 12 is to be formed. At this time, there is an unavoidable positioning error in the formation position of the resist mask 31; and the relative position of the resist mask 31 with respect to the semiconductor substrate 10 fluctuates within a constant range.

Continuing, ion implantation of the p-type impurity is performed using the resist mask 31 as a mask. At this time, the ion implantation often is performed in a direction tilted slightly with respect to the upward perpendicular direction, i.e., the direction perpendicular to the upper face of the semiconductor substrate 10, to suppress channeling effects. In the embodiment, the ion implantation is performed in a direction tilted, for example, 7° with respect to the upward perpendicular direction in the longitudinal direction of the gate electrode 17. The longitudinal direction of the gate electrode 17 is the gate width direction and is a direction parallel to the upper face of the semiconductor substrate 10 and orthogonal to the direction from the source region 21 of the transistor 11 toward the drain region 22 of the transistor 11. As illustrated in FIG. 3C, the high-concentration channel region 25 is formed in a portion of the upper portion of the semiconductor substrate 10 by the ion implantation. Subsequently, the resist mask 31 is removed.

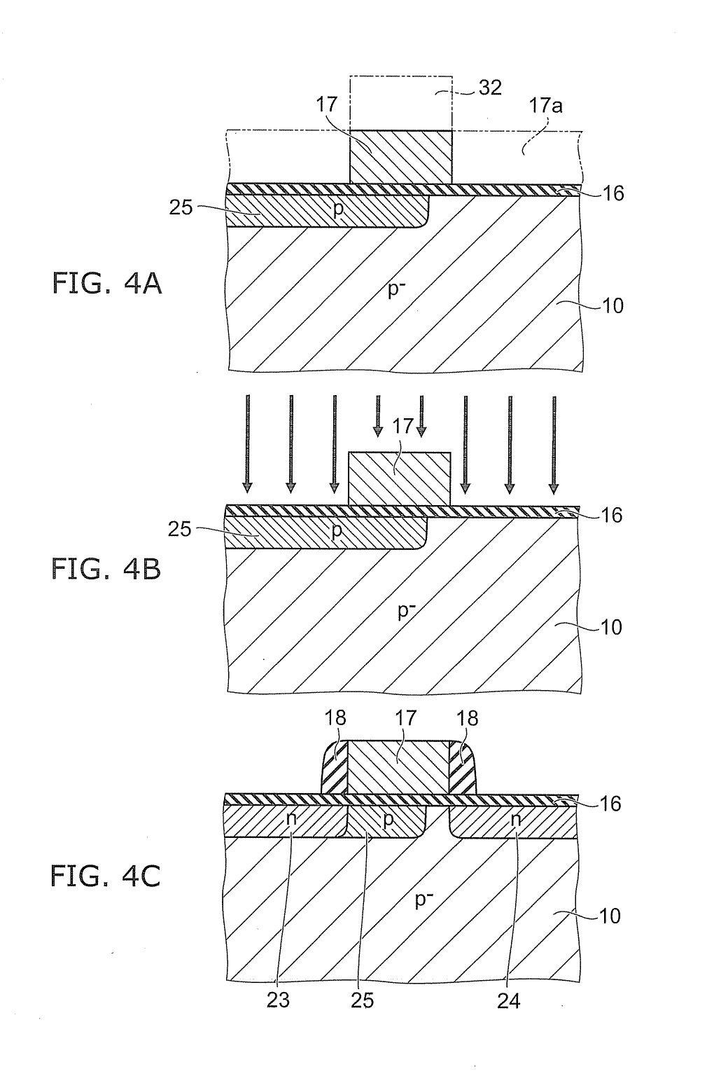

Then, as illustrated in FIG. 4A, a polycrystalline silicon film 17a is formed by depositing a gate electrode material such as polycrystalline silicon on the gate insulating film 16. Then, the gate electrode 17 is formed by forming a resist mask 32 on the polycrystalline silicon film 17a and patterning the polycrystalline silicon film 17a using the resist mask 32 as a mask. At this time, the resist mask used to pattern the gate electrode 17 is different from the resist mask 31 used when forming the high-concentration channel region 25. Therefore, the relative positions of the high-concentration channel region 25 and the gate electrode 17 unavoidably fluctuate undesirably due to the alignment shift of these resist masks.

Continuing as illustrated in FIG. 4B, ion implantation of the n-type impurity is performed using the gate electrode 17 as a mask. Thereby, as illustrated in FIG. 4C, the n-type LDD regions 23 and 24 are formed. Then, the sidewall 18 is formed on two side faces of the gate electrode 17 by forming an insulating film on the entire surface of the semiconductor substrate 10 to cover the gate electrode 17 and by performing etch-back.

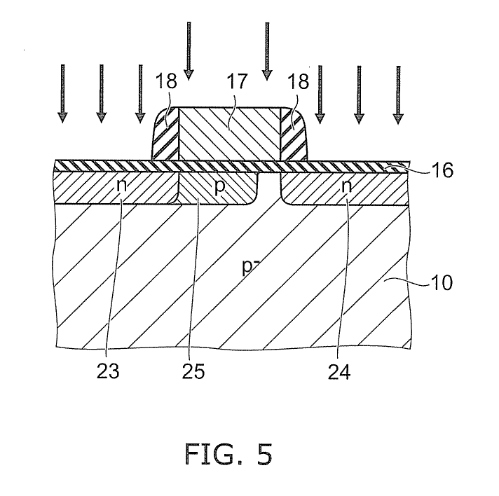

Then, as illustrated in FIG. 5, ion implantation of the n-type impurity is performed using the gate electrode 17 and the sidewall 18 as a mask. Thereby, the n⁺-type source region 21 and the n⁺-type drain region 22 are formed by re-implanting the n-type impurity into portions of the LDD regions 23 and 24. At this time, the impurity is not re-implanted into the regions of the semiconductor substrate 10 directly under the sidewalls 18; and these regions remain as-is as the LDD regions 23 and 24. Then, a p⁺-type contact region (not illustrated) is formed by selectively performing ion implantation of the p-type impurity. Then, as illustrated in FIG. 2, the drain electrode 28 is formed on the drain region 22 while forming the source electrode 27 on the source region 21. Thus, the transistors 11 and 12 are formed in the upper face of the semiconductor substrate 10. Thereby, the semiconductor device 1 is manufactured.

Operational effects of the embodiment will now be described.

In the channel regions of the transistors 11 and 12 of the embodiment, the high-concentration channel region 25 is formed only in the portion on the source region 21 side and is not formed in the portion on the drain region 22 side. Thereby, the electric field between the channel region and the drain region 22 can be relaxed; the hot carrier resistance can be improved; and the reliability of the semiconductor device 1 can be increased.

In the manufacturing processes of the semiconductor device 1, alignment shift occurs unavoidably between the resist mask 31 used to form the high-concentration channel region 25 and the resist mask (not illustrated) used to form the gate electrode 17. Thereby, the relative positional relationship between the high-concentration channel region 25 and the gate electrode 17 fluctuates; and the length of the high-concentration channel region 25 in the lateral direction fluctuates. As a result, the electrical characteristics such as the threshold value and the on-voltage of the transistors 11 and 12 undesirably fluctuate.

Therefore, in the embodiment, the source region 21 and the drain region 22 are disposed on the same sides of the transistors 11 and 12, respectively, which are used as a pair. Thereby, in the case where the formation position of the resist mask 31 shifts and, for example, the length of the high-concentration channel region 25 increases in the transistor 11, the length of the high-concentration channel region 25 in the transistor 12 also increases. Conversely, in the case where the length of the high-concentration channel region 25 decreases in the transistor 11, the length of the high-concentration channel region 25 in the transistor 12 also decreases. In other words, even in the case where the formation position of the resist mask 31 shifts, the pairability does not worsen because the electrical characteristics of the transistors 11 and 12 fluctuate in the same direction by the same amount. For example, the difference between the threshold values of the transistors 11 and 12 does not increase because the threshold values increase or decrease by substantially the same amount.

These effects will now be described based on specific data.

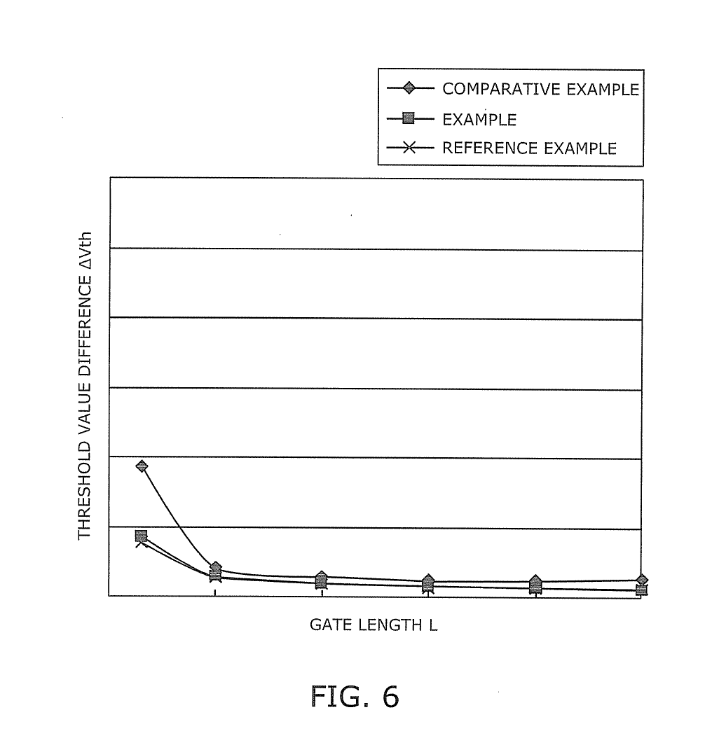

FIG. 6 is a graph illustrating the relationship between the element size and the pairability. The gate length is illustrated on the horizontal axis and the threshold value difference is illustrated on the vertical axis.

The reference example illustrated in FIG. 6 is the case where a normal CMOS (complementary metal oxide semiconductor) transistor is used. Even for the normal CMOS transistor, which has a constant impurity concentration inside the channel region, a threshold value difference ΔVth starts to increase from some point as a gate length L is reduced. In other words, the pairability starts to worsen when the element size is reduced below some size.

The example illustrated in FIG. 6 is an example of the embodiment in which, as described above, the arrangement directions of the source/drain are matched between the two transistors used as a pair. According to the example of the embodiment as illustrated in FIG. 6, it is possible to obtain a pairability similar to that of the CMOS transistor.

The comparative example illustrated in FIG. 6 is an example in which the arrangement directions of the source/drain are reversed from each other for the two transistors used as the pair. In the comparative example as illustrated in FIG. 6, the threshold value difference ΔVth is greater than those of the reference example and the example when the gate length L is reduced. In other words, the pairability worsens more markedly in the comparative example than in the example of the embodiment when the element size is reduced.

Also, in the process illustrated in FIG. 3B of the embodiment, the ion implantation used to form the high-concentration channel region 25 is performed in a direction tilted with respect to the upward perpendicular direction. Thereby, channeling effects can be suppressed. In the manufacturing processes of a normal CMOS, the ion implantation is already performed in the tilted direction described above to suppress the channeling effects. Therefore, it is unnecessary to modify the channel formation process or add a new process to form the GCMOS of the embodiment. Further, the throughput of the manufacturing processes does not decrease because the high-concentration channel region 25 can be formed by one ion implantation. In the embodiment, the direction of the ion implantation is a direction tilted with respect to the upward perpendicular direction in the longitudinal direction of the gate electrode 17. Thereby, the position of the end edge of the high-concentration channel region 25 on the drain region 22 side shifts little with respect to the position of the end edge of the resist mask 31 on the source region 21 side. In other words, the high-concentration channel region 25 can be formed with high precision with respect to the resist mask 31. This effect is particularly effective in the case where the gate length is short.

A second embodiment will now be described.

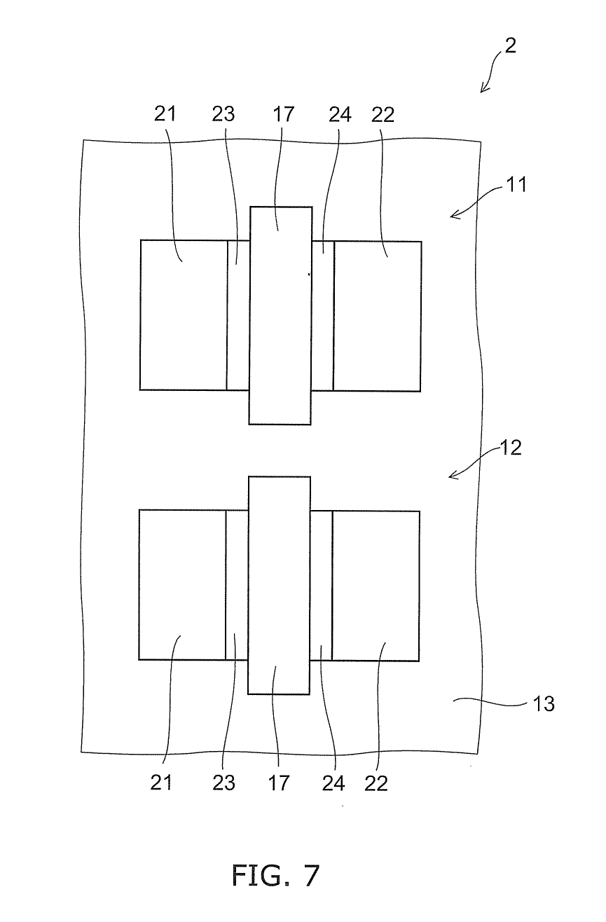

FIG. 7 is a plan view illustrating a semiconductor device according to the embodiment.

In the embodiment as illustrated in FIG. 7, the arrangement direction of the transistors 11 and 12 is different from that of the first embodiment described above. In other words, in the semiconductor device 2 according to the embodiment, the direction from the source region 21 of the transistor 11 toward the source region 21 of the transistor 12 is orthogonal to the direction from the source region 21 of the transistor 11 toward the drain region 22 of the transistor 11. Thereby, the source region 21 and the drain region 22 of the transistor 11 and the source region 21 and the drain region 22 of the transistor 12 are arranged in a matrix configuration having two rows and two columns.

Otherwise, the configuration and the manufacturing method of the embodiment are similar to those of the first embodiment described above. In other words, in the embodiment as well, the direction from the source region 21 of the transistor 11 toward the drain region 22 of the transistor 11 has the same orientation as the direction from the source region 21 of the transistor 12 toward the drain region 22 of the transistor 12. In other words, the side of the transistor 11 on which the source region 21 is disposed as viewed from the gate electrode 17 is the same as the side of the transistor 12 on which the source region 21 is disposed as viewed from the gate electrode 17. According to the embodiment as well, effects similar to those of the first embodiment described above can be obtained.

A third embodiment will now be described.

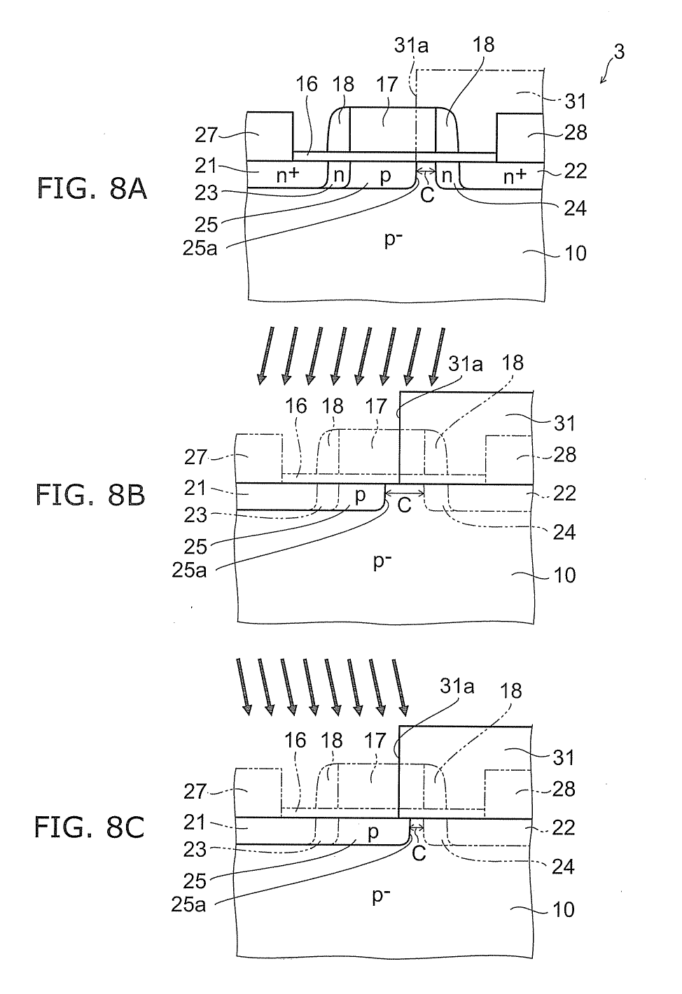

FIG. 8A is a cross-sectional view illustrating a semiconductor device according to the embodiment. FIGS. 8B and 8C are cross-sectional views of processes, illustrating a method for manufacturing the semiconductor device according to the embodiment.

Although FIG. 8A illustrates a transistor 3 after completion, the resist mask 31 used in the intermediate processes also is illustrated for reference. Although FIGS. 8B and 8C illustrate the method for manufacturing the transistor 3, the gate electrode 17, etc., formed in subsequent processes also are illustrated for reference.

In the embodiment, the tilt direction of the ion implantation used to form the high-concentration channel region 25 is different from that of the first embodiment described above. In the embodiment, the ion implantation used to form the high-concentration channel region 25 in the process illustrated in FIG. 3B described above is performed in a direction tilted with respect to the upward perpendicular direction in the gate length direction, i.e., the direction linking the source region 21 to the drain region 22.

A distance C between the high-concentration channel region 25 and the LDD region 24 often is constant in the GCMOS transistor 3 as illustrated in FIG. 8A. In the manufacturing processes of the GCMOS transistor, an end edge 31a of the resist mask 31 on the source region 21 side is positioned in the region directly above an end edge 25a of the region where the high-concentration channel region 25 is to be formed on the drain region 22 side.

However, in the case where the ion implantation used to form the high-concentration channel region 25 is performed in a direction tilted with respect to the upward perpendicular direction toward the drain region 22 side as illustrated in FIG. 8B, the end edge 25a of the high-concentration channel region. 25 actually formed shifts toward the source region 21 side from the end edge 31a of the resist mask 31. In other words, the distance C becomes greater than the design value.

Conversely, as illustrated in FIG. 8C, in the case where the ion implantation is performed in a direction tilted with respect to the upward perpendicular direction toward the source region 21 side, the end edge 25a of the high-concentration channel region 25 actually formed shifts toward the drain region 22 side from the end edge 31a of the resist mask 31. In other words, the distance C becomes less than the design value.

Even in such a case, according to the embodiment, the arrangement direction of the source region 21 and the drain region 22 is the same for the transistors 11 and 12. Therefore, the direction and the amount that the end edge 25a of the high-concentration channel region 25 shifts with respect to the end edge 31a of the resist mask 31 is the same for both of the transistors. For example, in the case where the distance C of the transistor 11 is large, the distance C of the transistor 12 also is large. As a result, the trend of the fluctuation of the electrical characteristics caused by the ion implantation direction is the same for the transistors 11 and 12; and the pairability can be prevented from worsening. Otherwise, the configuration, manufacturing method, and operational effects of the embodiment are similar to those of the first embodiment described above.

The embodiments described above may be implemented in combination with each other. For example, in the second embodiment described above as well, the direction of the ion implantation used to form the high-concentration channel region 25 may be tilted from the upward perpendicular direction toward the source region side or the drain region side similarly to the third embodiment described above. The ion implantation used to form the high-concentration channel region 25 may be performed in a direction tilted with respect to the upward perpendicular direction toward both the gate length direction and the gate width direction. Although an example is illustrated in the embodiments described above in which the transistors 11 and 12 are disposed adjacent to each other, this is not limited thereto. Other elements may be formed between the transistors 11 and 12. Although an example is illustrated in the embodiments described above in which an n-channel transistor is formed in the upper face of a p⁻-type substrate, this is not limited thereto. A p-channel transistor may be formed in the upper face of an n⁻-type substrate.

According to the embodiments described above, a semiconductor device can be realized with little fluctuation of the electrical characteristics due to the process fluctuation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a semiconductor substrate having a first conductivity type; and
first and second transistors provided on the semiconductor substrate,
the first and second transistors each including
a gate electrode provided on the semiconductor substrate,
a gate insulating film provided between the semiconductor substrate and the gate electrode,
a source region and a drain region of a second conductivity type provided in regions of an upper portion of the semiconductor substrate, a region directly under the gate electrode being interposed between the source region and the drain region, and
a high-concentration channel region of the first conductivity type formed on a side of the source region of the region of the upper portion directly under the gate electrode, the high-concentration channel region having an effective impurity concentration higher than an effective impurity concentration of the upper portion,
a direction from the source region of the first transistor toward the drain region of the first transistor having an orientation being substantially same as a direction from the source region of the second transistor toward the drain region of the second transistor.

2. The device according to claim 1, wherein the first transistor and the second transistor are disposed adjacent to each other.

3. The device according to claim 1, wherein the first transistor and the second transistor are included in one circuit.

4. The device according to claim 1, wherein a direction from the source region of the first transistor toward the source region of the second transistor substantially matches the direction from the source region of the first transistor toward the drain region of the first transistor.

5. The device according to claim 1, wherein a direction from the source region of the first transistor toward the source region of the second transistor is substantially orthogonal to the direction from the source region of the first transistor toward the drain region of the first transistor.

6. The device according to claim 1, wherein the first transistor and the second transistor each further include:
a sidewall provided on a side face of the gate electrode; and
an LDD region provided in a region of the upper portion directly under the sidewall, the LDD region having an effective impurity concentration lower than effective impurity concentrations of the source region and the drain region.

7. The device according to claim 1, wherein the high-concentration channel region is formed by implanting an impurity in a direction tilted with respect to a direction perpendicular to the upper face of the semiconductor substrate toward a direction orthogonal to the direction from the source region of the first transistor toward the drain region of the first transistor.

8. The device according to claim 1, wherein the high-concentration channel region is formed by implanting an impurity in a direction tilted with respect to a direction perpendicular to the upper face of the semiconductor substrate toward the direction from the source region of the first transistor toward the drain region of the first transistor.

9. The device according to claim 1, wherein the high-concentration channel region is formed by implanting an impurity in a direction tilted with respect to a direction perpendicular to the upper face of the semiconductor substrate toward both a first direction from the source region of the first transistor toward the drain region of the first transistor and a second direction orthogonal to the first direction.

10. A method for manufacturing a semiconductor device, comprising:
partitioning a first region and a second region by selectively forming an element isolation insulating film in an upper portion of a semiconductor substrate, the upper portion having a first conductivity type;
forming a gate insulating film in an upper face of the semiconductor substrate;
selectively forming a first mask material on the gate insulating film on a side of one-direction of a region directly above the first region and on the gate insulating film on a side of the one-direction of a region directly above the second region;
forming a high-concentration channel region in a portion of the upper portion of the semiconductor substrate by implanting a first conductivity-type impurity using the first mask material as a mask;
removing the first mask material;
forming a conductive film on the gate insulating film;
selectively forming a second mask material on the conductive film;
forming a gate electrode by selectively removing the conductive film by performing etching using the second mask material as a mask;
forming an LDD region by implanting a second conductivity-type impurity using the gate electrode as a mask;
forming a sidewall on a side face of the gate electrode; and
forming a source region and a drain region in the upper portion of the semiconductor substrate by implanting the second conductivity-type impurity using the gate electrode and the sidewall as a mask.

11. The method according to claim 10, wherein the one direction is a direction from the first region substantially toward the second region.

12. The method according to claim 10, wherein the one direction is a direction orthogonal to a direction from the first region substantially toward the second region.

13. The method according to claim 10, wherein the implanting of the first conductivity-type impurity is performed in a direction tilted with respect to a direction perpendicular to the upper face of the semiconductor substrate toward a direction orthogonal to the one direction.
